(19) United States
(12) Patent Application Publication
(10) Pub. No.: US 2020/0266188 A1
(43) Pub. Date: Aug. 20, 2020

(54) SEMICONDUCTOR DEVICE, AND HIGH VOLTAGE DEVICE WITH SELF-ELECTROSTATIC DISCHARGE PROTECTION

(71) Applicant: CSMC TECHNOLOGIES FAB2 CO., LTD., Wuxi New District, Jiangsu (CN)

(72) Inventor: Guangyang WANG, Wuxi (CN)

(21) Appl. No.: 16/644,462

(22) PCT Filed: Aug. 3, 2018
(86) PCT No.: PCT/CN2018/098511

§ 371 Date: Mar. 4, 2020

(30) Foreign Application Priority Data
Aug. 3, 2017 (CN) 201710656774.3

(51) Int. Cl. H01L 27/02; H01L 23/60; H01L 27/06

(52) U.S. Cl. CPC H01L 27/0259; H01L 27/0623; H01L 23/60

(57) ABSTRACT

A high voltage device with self-electrostatic discharge protection. The device comprises: a semiconductor substrate; a first N-well (201), a P-well (202), and a second N-well (209) formed in the semiconductor substrate; a first N+ ion implantation region (203) and a first isolation region (207) formed in the first N-well (201); a second N+ ion implantation region (204) and a P+ ion implantation region (205) adjacent to the second N+ ion implantation region (204) that are formed in the P-well (202); a third N+ ion implantation region (208) formed in the second N-well (209); and a second isolation region (210) formed in the semiconductor substrate, the second isolation region (210) covering a portion of the second N-well (209) and a portion of the P-well (202), wherein the second N+ ion implantation region (203), the P+ ion implantation region (205), and the third N+ ion implantation region (208) constitute an NPN-type BJT, and the electrostatic discharge protection is achieved by means of the BJT.

### CROSS REFERENCES TO RELATED APPLICATIONS

This patent application claims priority to Chinese patent application No. 201710656774.3, filed on Apr. 3, 2017, the disclosure of which is hereby incorporated by reference in its entirety.

### TECHNICAL FIELD

The present disclosure relates to the field of semiconductor manufacturing, and particularly relates to a semiconductor device and a high voltage (HV) device with self-electrostatic discharge (ESD) protection.

### BACKGROUND

Electrostatic discharge is a natural phenomenon commonly exists in our lives, yet a large current generated in a short time during electrostatic discharge can cause fatal damage to an integrated circuit, which is an important problem that causes failure in the production and application of the integrated circuit. For example, an electrostatic discharge phenomenon that occurs on the human body usually occurs within a few hundred nanoseconds, and the maximum current peak value thereof may reach several amperes. And an electrostatic discharge in another mode occurs in a shorter time and has a larger current. Such a large current passes through the integrated circuit in a short time, the power consumption generated will seriously exceed the maximum value the integrated circuit can withstand, which will cause severe physical damage to the integrated circuit and finally cause failure to the integrated circuit.

This problem is mainly solved from two aspects of the environment and the circuit itself in practical applications. In the aspect of the environment, it is mainly to reduce the generation of static electricity and eliminate static electricity timely, such as applying materials that are not easy to generate static electricity, increasing environmental humidity, operators, and grounding the equipment. In the aspect of the circuit, it is mainly to increase the electrostatic discharge tolerance of the integrated circuit itself, such as adding an additional electrostatic protection device or circuit to protect the internal circuit of the integrated circuit from being damaged by electrostatic discharge.

### SUMMARY

According to various embodiments of the present disclosure, a high voltage device with self-electrostatic discharge protection is provided. The high voltage device includes a semiconductor substrate, a first N-well, a P-well, a second N-well, a first N+ ion implanted region, a first isolation region, a second N+ ion implanted region, a P+ ion implanted region, a third N+ ion implanted region, and a second isolation region. The first N-well, the P-well, and the second N-well are formed in the semiconductor substrate. The first N+ ion implanted region and the first isolation region are formed in the first N-well. The second N+ ion implanted region and the P+ ion implanted region next to the second N+ ion implanted region are formed in the P-well. The third N+ ion implanted region is formed in the second N-well. The second isolation region is formed in the semiconductor substrate. The second isolation region covers part of the second N-well and part of the P-well. The second N+ ion implanted region, the P+ ion implanted region and the third N+ ion implanted region constitute an NPN-type And the electrostatic discharge protection is achieved through the BIT.

The details of one or more embodiments of this disclosure are set forth in the accompanying drawings and description below. Other features, objects and advantages of the present disclosure will become apparent from the description, the accompanying drawings, and the claims.

### BRIEF DESCRIPTION OF THE DRAWINGS

To better describe and illustrate embodiments and/or examples of the disclosure disclosed herein, reference can be made to one or more accompanying drawings. The additional details or examples used to describe the accompanying drawings should not be construed as limiting the scope of any of the disclosed disclosure, the presently described embodiments and/or examples, and the presently understood optional mode of the disclosure.

FIG. 1 is a schematic diagram of a conventional high voltage device with self-electrostatic protection,

FIG. 2 is a schematic diagram of a high voltage device with self-electrostatic protection according to an exemplary embodiment of the present disclosure.

### DETAILED DESCRIPTION

In the description hereafter, numerous specific details are set forth in order to provide a more thorough understanding of the present disclosure. However, it will be apparent to those skilled in the art that the present disclosure may be implemented without one or more of these details. In other examples, in order to avoid confusion with the present disclosure, some technical features known in the art are not described.

It should be understood that the present disclosure can he embodied in different forms and should not be construed as limited to the embodiments set forth herein. Rather, providing these embodiments will make the disclosure thorough and complete, and fully convey the scope of the present disclosure to those skilled in the art. In the accompanying drawings, the sizes and relative sizes of layers and regions may be exaggerated for clarity. The same reference numerals denote the same elements from beginning to end.

It should be understood that, when an element or layer is described as being “on”, “adjacent to”, “connected to” or “coupled to” another element or layer, it can be directly on, adjacent to, connected to, or coupled to the other element or layer, or there can be an intermediate element. In contrast, when an element is described as being “directly on”, “directly adjacent to”, “directly connected to”, or “directly coupled to” another element or layer, there is no intermediate element or layer. It should be understood that, although the terms of “first”, “second”, “third”, and so on can be used to describe various elements, components, regions, layers and/or portions, these elements, components, regions, layers and/or portions should not be limited by these terms. These terms are merely used to distinguish an element, component, region, layer or portion from another element, component, region, layer or portion. Thus, the first element, component, region, layer or portion discussed below can be described as a second element, component, region, layer or portion without departing from the teachings of the present disclosure.

Spatial relation terms such as “below”, “beneath”, “under”, “above”, “on”, etc., can be used herein for convenience of description to describe the relationship between an element or feature and another element or feature shown in the figures, It should be understood that, in addition to the orientations shown in the figures, the spatial relationship terms are intended to include different orientations of the devices in use and operation. For example, if a device in the figures is turned over, then the element or feature described as “below” or “beneath” another element or feature would then be oriented as “above” the other element or feature, Thus, the exemplary terms “below” and “beneath” can include both orientations of above and below. The device may be otherwise oriented (rotated 90 degrees or otherwise) and the spatial descriptions used herein are interpreted accordingly.

Terms used herein are for the purpose of describing specific embodiments only and are not intended to be limiting of the present disclosure. As used herein, “a”, “one” and “said/the” in singular forms are also intended to include a plural form unless the context clearly indicates other forms. It should also be understood that the terms “consist” and/or “include” when used in the description, determine presence of the features, integers, steps, operations, elements and/or components, but do not exclude the presence or addition of one or more other features, integers, steps, operations, elements, components, and/or groups. As used herein, the terms “and/or” include any and all combinations of related listed items.

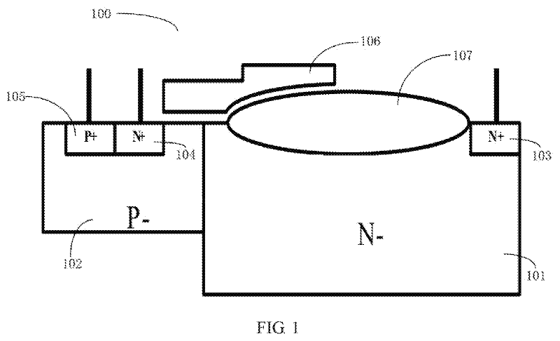

A conventional high voltage device 100 is shown in FIG. 1. An N-well 101 and a P-well 102 are formed in a semiconductor substrate. A depth of the P-well 102 is smaller than a depth of the N-well 101. A first N+ ion implanted region 103 as a drain electrode of the high voltage device 100 is formed in the N-well 101. A second N+ ion implanted region 104 as a source electrode of the high voltage device 100 is formed in the P-well 102. A P+ ion implanted region 105 next to the second N+ ion implanted region 104 is further formed in the P-well 102. An isolation region 107 is further formed in the N-well 101. The gate electrode 106 of the high voltage device 100 covers part of the P-well 102, part of the N-well 101, and part of the isolation region 107.

Due to its large operating voltage and large area occupation on the area of the chip, the conventional high voltage device 100 relies on its own circuit structure to achieve electrostatic discharge protection. As shown in FIG. 1, when an electrostatic discharge is generated inside the high-voltage device 100, a current caused by the electrostatic discharge flows from the first N+ ion implanted region 103 as a drain electrode of the high voltage device 100 to the P+ ion implanted region 105 and the second N+ ion implanted region 104 as the source electrode of the high voltage device 100 via the N-well 101 and the P-well 102, such that an electrostatic discharge protection for itself is accomplished.

However, in order to optimize parameters such as the linear resistance (R_{dson}) of the linear region of the MOS tube, it is difficult for the conventional high voltage device 100 to achieve good electrostatic discharge protection. To this end, the present disclosure provides a high voltage device that achieves self-electrostatic discharge protection. This high voltage device uses a BJT at the bottom of the substrate to implement the electrostatic discharge protection, and can separate its own electrostatic discharge protection capability from the optimization of the parameters such as the R_{dson}, thereby reducing the development of the high-voltage devices and finally reducing the cost.

In order to thoroughly understand the present disclosure, detailed structures and/or detailed steps will be set forth in the following description, so as to explain the technical solutions proposed by the present disclosure. Optional embodiments of the present disclosure are described in detail below, however in addition to these detailed description, the present disclosure may have other embodiments.

The present disclosure provides a semiconductor device, including a semiconductor substrate, a first well, a drain region, a source region, a first doped region, a second doped region, and a second doped region.

The first well, the second well, and the third well are formed in the semiconductor substrate. The third well is located between the first well and the second well. The first well and the second well have a first conductivity type. The third well has a second conductivity type. And the first conductivity type and the second conductivity type are opposite conductivity types.

The drain region is formed in the first well and has a first conductivity type.

The source region is formed in the third well and has a first conductivity type.

The first doped region is formed in the second well and has a first conductivity type.

The second doped region is formed in the third well and has a second conductivity type. The source region, the second doped region, and the first doped region constitute a bipolar junction transistor.

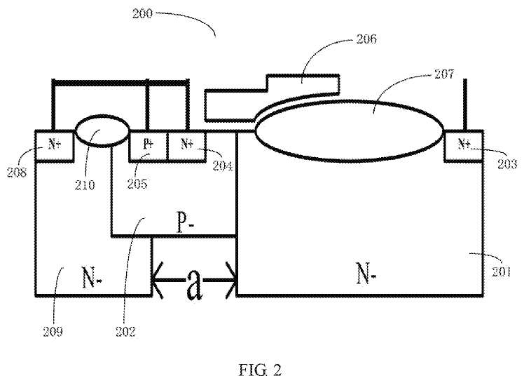

A high voltage device 200 with self-electrostatic discharge protection proposed in the present disclosure is shown in FIG. 2. A first N-well 201, a P-well 202 and a second N-well 209 are formed in a semiconductor substrate. A depth of the P-well 202 is less than a depth of the first N-well 201, and the depth of the first N-well 201 and a depth of the second N-well 209 are the same. A distance between the first N-well 201 and the second N-well 209 is a. Electrostatic discharge protection at different voltages is achieved by adjusting value of a. When adjusting the value of a, it is ensured that part of the second N-well 209 is formed below the P-well 202.

A first N+ ion implanted region 203 as a drain electrode of the high voltage device 200 is formed in the first N-well 201. A second N+ ion implanted region 204 as a. source electrode of the high voltage device 200 is formed in the P-well 202, A P+ ion implanted region 205 next to the second N+ ion implanted region 204 is further formed in the P-well 202. A third N+ ion implanted region 208 is formed in the second N-well 209. A first isolation region 207 is further formed in the first N-well 201. A gate electrode 206 of the high voltage device 200 covers part of the P-well 202, part of the first N-well 201, and part of the first isolation region 207. A second isolation region 210 is further formed in the semiconductor substrate. The second isolation region 210 covers part of the second N-well 209 and part of the P-well 202.

The second N+ ion implanted region 204, the P+ ion implanted region 205, and the third N+ ion implanted region 208 constitute an NPN-type BJT, in which the second. N+ ion implanted region 204 serves as a collecting electrode of the BJT, the P ion implanted region 205 serves as a base electrode of the BJT, and the third N+ ion implanted region 208 serves as an emitting electrode of the BJT.

As shown in FIG. 2, when an electrostatic discharge is generated inside the high voltage device 200, a current caused by the electrostatic discharge flows from the first N+ion implanted region 203 as the drain electrode of the high voltage device 200 to the third N+ ion implanted region 208 via the first N-well 201 and the second N-well 209, such that an electrostatic discharge protection for the high voltage device 200 is accomplished. The main withstand voltage region of the high-voltage device 200 is in the first N+ ion implanted region 203 as the drain electrode. Therefore, by adjusting the value of the distance a between the first N-well 201 and the second N-well 209, the BJT is triggered first such that the current caused by the electrostatic discharge flows from the first N+ ion implanted region 203 as the drain electrode of the high voltage device 200 to the third N ion implanted region 208 via the first N-well 201 and the second N-well 209, rather than to the P+ ion implanted region 205 and the second N+ ion implanted region 204 as the source electrode of the high voltage device 200 via the first N-well 201 and the P-well 202.

In the present disclosure, a strong electrostatic discharge protection capability for the high-voltage device 200 can be achieved through the BJT at a bottom of the substrate, thereby separating the electrostatic discharge self-protection of the traditional high voltage device separately and reducing the development difficulty of the high voltage device, and more area can be saved under the same electrostatic discharge protection capability, and the market competitiveness of the products is improved.

As an example, the gate electrode 206 of the high voltage device 200 includes a gate dielectric layer and a gate material layer that are sequentially stacked from bottom to top, and sidewall structures are formed on both sides of the gate electrode 206.

As an example, the gate dielectric layer includes an oxide layer, such as a silicon dioxide (SiO2) layer, The gate material layer includes one or more of a polysilicon layer, a metal layer, a conductive metal nitride layer, a conductive metal oxide layer, and a metal silicide layer. A constituent material of the metal layer can be tungsten (W), nickel (Ni) or titanium (Ti); the conductive metal nitride layer includes a titanium nitride (TiN) layer; the conductive metal oxide layer includes an iridium oxide (IrO2) layer; and the metal silicide layer includes a titanium silicide (TiSi) layer, The gate dielectric layer and the gate material layer can be formed by any existing technology familiar to those skilled in the art, optionally by chemical vapor deposition (CND), such as low temperature chemical vapor deposition (LTCVD), low pressure chemical vapor deposition (LPCVD), rapid thermal chemical vapor deposition (RTCVD), and plasma enhanced chemical vapor deposition (PECVD).

As an example, the first N-well 201 and the second N-well 209 are formed simultaneously, the first isolation region 207 and the second isolation region 210 are formed simultaneously, and the first N+ ion implanted region 203, the second N+ ion implanted region 204, and the third N+ ion implanted region 208 are formed simultaneously. After the first N-well 201 and the second N-well 209 are formed, the P-well 202 is formed.

The present disclosure has been described through the above embodiments, but it should be understood that, the above embodiments are merely for the purpose of illustration and description, and are not intended to limit the present disclosure to the scope of the described embodiments. In addition, those skilled in the art can understand that, the present disclosure is not limited to the above described embodiments, further variations and modifications can be made according to the teachings of the present disclosure, and these variations and modifications all fall within the claimed protection scope of the present disclosure. The protection scope of the present disclosure is defined by the appended claims and equivalent scope thereof.

1. A high voltage device with self-electrostatic discharge protection, comprising:
a semiconductor substrate;
a first N-well, a P-well, and a second N-well formed in the semiconductor substrate;
a first N+ ion implanted region and a first isolation region formed in the first N-well;
a second N+ ion implanted region and a P+ ion implanted region next to the second N+ ion implanted region which are formed in the P-well;
a third N+ ion implanted region formed in the second N-well; and
a second isolation region formed in the semiconductor substrate, the second isolation region covering part of the second N-well and part of the P-well, wherein the second N+ ion implanted region, the P+ ion implanted region and the third N+ ion implanted region constitute an NPN-type BJT, and the electrostatic discharge protection is achieved through the BJT.

2. The high voltage device according to claim 1, wherein the second N+ ion implanted region serves as a collecting electrode of the BJT, the P+ ion implanted region serves as a base electrode of the BJT, and the third N+ ion implanted region serves as an emitting electrode of the BJT.

3. The high voltage device according to claim 1, wherein the first N-well and the second N-well are formed at a same time and have a same depth.

4. The high voltage device according to claim 1, wherein electrostatic discharge protection at different voltages is achieved by adjusting value of a distance between the first N-well and the second N-well.

5. The high voltage device according to claim 4, wherein it is ensured that part of the second N-well is formed below the P-well when adjusting the value of the distance.

6. The high voltage device according to claim 1, wherein a depth of the P-well is smaller than a depth of the first N-well.

7. The high voltage device according to claim 1, wherein the first N+ ion implanted region serves as a drain electrode of the high voltage device, and the second N+ ion implanted region serves as a source electrode of the high voltage device.

8. The high voltage device according to claim 1, wherein a current caused by an electrostatic discharge flows from the first N+ ion implanted region to the third N+ ion implanted region via the first N-well and the second N-well.

9. The high voltage device according to claim 8, wherein the electrostatic discharge protection for the high voltage device is accomplished by adjusting value of a distance between the first N-well and the second N-well to trigger the BJT first.

10. The high voltage device according to claim 1, further comprising a gate electrode formed on the semiconductor substrate, the gate electrode covering part of the P-well, part of the first N-well, and part of the first isolation region.

11. A semiconductor device, comprising:
a semiconductor substrate;
a first well, a second well, and a third well formed in the semiconductor substrate, the third well being located between the first well and the second well, the first well and the second well having a first conductivity type, the third well having a second conductivity type, and the first conductivity type and the second conductivity type being opposite conductivity types;
a drain region formed in the first well and having the first conductivity type;
a source region formed in the third well and having the first conductivity type;
a first doped region formed in the second well and having the first conductivity type; and
a second doped region formed in the third well and having the second conductivity type; the source region, the second doped region, and the first doped region constituting a bipolar junction transistor.

12. The semiconductor device according to claim 11, wherein the second doped region is located between the source region and the first doped region.

13. The semiconductor device according to claim 11, wherein the first conductivity type is an N type and the second conductivity type is a P type.

14. The semiconductor device according to claim 13, wherein the first well is a first N-well, the second well is a second N-well, the third well is a P-well, the drain region is a first N+ ion implanted region, the source region is a second N+ ion implanted region, the first doped region is a third N+ ion implanted region, and the second doped region is a P+ ion implanted region; the second N+ ion implanted region serves as a collecting electrode of a BJT, the P+ ion implanted region serves as a base electrode of the BJT, and the third N+ ion implanted region serves as an emitting electrode of the BJT.

15. The semiconductor device according to claim 11, further comprising a first isolation region formed between the drain region and the source region.

16. The semiconductor device according to claim 11, further comprising a second isolation region formed between the first doped region and the second doped region.

17. The semiconductor device according to claim 11, wherein part of the second well is located below the third well.

18. The semiconductor device according to claim 15, further comprising a gate electrode formed on the semiconductor substrate, the gate electrode covering part of the third well, part of the first well, and part of the first isolation region.

19. The semiconductor device according to claim 11, wherein a depth of the third well is smaller than a depth of the first well.

20. The semiconductor device according to claim 11, wherein a current caused by an electrostatic discharge flows from the drain region to the first doped region via the first well and the second well.
